(19) United States
(12) Patent Application Publication
(10) Pub. No.: US 2026/0009864 A1
(43) Pub. Date: Jan. 8, 2026

(54) ELECTRICAL TESTING DEVICE, METHOD AND STORAGE MEDIUM

(71) Applicant: Fulian Precision Electronics (Tianjin) Co., LTD., Tianjin (CN)

(72) Inventors: CHI-WEN CHEN, New Taipei (TW); Wei-Ming LEE, New Taipei (TW)

(21) Appl. No.: 18/962,153

(22) Filed: Nov. 27, 2024

(30) Foreign Application Priority Data
Jul. 5, 2024 (CN) 202410897852.9

(51) Int. Cl. G01R 31/40

(52) U.S. Cl. CPC G01R 31/40

(57) ABSTRACT

The present application discloses an electrical testing device, an electrical testing method and a storage medium. The electrical testing device includes a power supply, a capacitive load device used to provide a capacitive load for the power supply, and a testing device. The testing device is used to test electrical information of the power supply according to the capacitive load. The capacitive load device comprises a capacitor, a switch and a microcontroller. The capacitor is connected to the testing device and used to provide the capacitive load for the power supply by the testing device. The switch is connected to the capacitor and used to control connection and disconnection between the capacitor and the power supply. The microcontroller is connected to the switch and is used to control the connection and disconnection of the switch according to a level signal received by the microcontroller.

This application claims priority to Chinese Patent Application No. 202410897852.9 filed on Jul. 5, 2024, in China National Intellectual Property Administration, the contents of which are incorporated by reference herein.

### FIELD

The present application belongs to a field of testing technology, and in particular, relates to an electrical testing device, an electrical testing method and a storage medium.

### BACKGROUND

With the diversification of applications and functions of various electronic devices, the power consumption of electronic devices is getting faster and faster, and power supplies are needed to charge them in time. Before a power supply leaves the factory, its electrical performance needs to be tested to ensure that the power supply can meet the design and safety standards.

In the related art, when verifying the electrical properties of the power supply, it is usually tested by adding or removing capacitor loads according to custom specifications. The above method requires operators to repeatedly plug and unplug capacitors, which reduces the life of the capacitors; and due to the limitations of the operator's experience, an accuracy and a speed of electrical testing are low.

### BRIEF DESCRIPTION OF THE DRAWINGS

FIG. 1 is a structure schematic diagram of an electrical testing device provided in an embodiment of the present application.

FIG. 2 is a structure schematic diagram of a capacitive load device provided in an embodiment of the present application.

FIG. 3 is a schematic diagram of an electrical testing circuit provided in an embodiment of the present application.

FIG. 4 is a flow chart of an electrical testing method provided in an embodiment of the present application.

FIG. 5 is a flow chart of a method for determining a capacitive load device provided in an embodiment of the present application.

FIG. 6 is a flow chart of a method for testing electrical information provided in an embodiment of the present application.

### REFERENCE NUMBER

1, electrical testing device; 10, power supply; 20, capacitive load device; 21, motherboard; 22, capacitance; 23, switch; 24, microcontroller; 25, first connection part; 26, resistance; 30, testing device; 31, second connection part.

### DETAILED DESCRIPTION

The embodiments of the present application are described in detail below, and examples of the embodiments are shown in the accompanying drawings, wherein the same or similar reference numerals in the specification represent the same or similar elements or elements having the same or similar functions. The embodiments described below with reference to the accompanying drawings are exemplary and are only used to explain the present application, and cannot be understood as limiting the present application.

In the description of the present application, it should be understood that the terms indicating an orientation or positional relationship are based on the orientation or positional relationship shown in the accompanying drawings, and are only for the convenience of describing the present application and simplifying the description, rather than indicating or implying that the device or element referred to must have a specific orientation, be constructed and operated in a specific orientation, and therefore cannot be understood as a limitation on the present application. In addition, the terms “first” and “second” are used for descriptive purposes, and cannot be understood as indicating or implying relative importance or implicitly indicating the number of technical features indicated. Thus, the features defined as “first” and “second” may explicitly or implicitly include one or more of the features. In the description of the present application, it should be noted that the meaning of “multiple” is two or more, unless otherwise clearly and specifically defined.

In the description of the present application, it should be noted that, unless otherwise clearly specified and limited, the terms “installed”, “connected”, and “connected” should be understood in a broad sense, for example, it can be a fixed connection, a detachable connection, or an integral connection; and it can be a mechanical connection, an electrical connection, or mutual communication, and it can be a direct connection, or an indirect connection through an intermediate medium, and it can be the internal connection of two elements or the interaction relationship between two elements. For ordinary technicians in this field, the specific meanings of the above terms in this application can be understood according to specific circumstances.

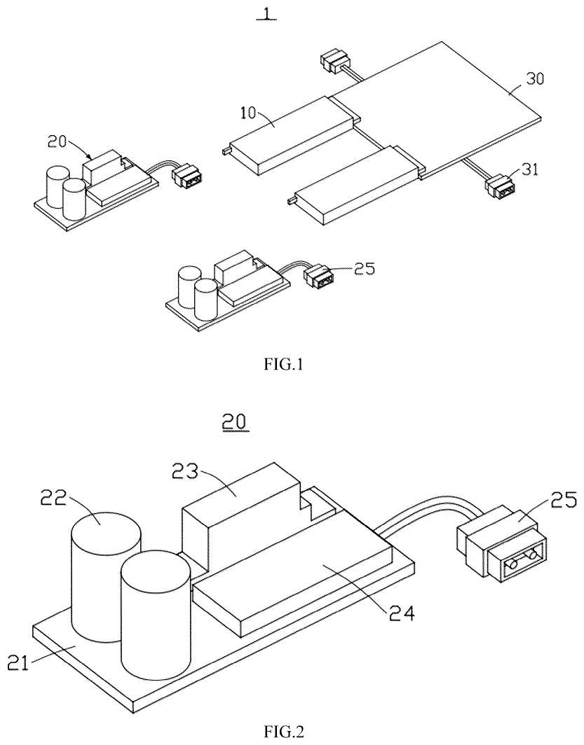

FIG. 1 is a structure schematic diagram of an electrical testing device provided in an embodiment of the present application. As shown in FIG. 1, the electrical testing device 1 includes a power supply 10, a capacitive load device 20 and a testing device 30. The capacitive load device 20 is used to provide a capacitive load for the power supply 10. The testing device 30 is respectively connected to the capacitive load device 20 and the power supply 10, and the testing device 30 is used to test the electrical information of the power supply 10 according to the capacitive load. In one embodiment, the power supply 10 is an electronic device that converts alternating current into direct current. In some embodiments, a testing device 30 can connect one capacitive load device 20 and one power supply 10, or the testing device 30 can connect multiple capacitive load devices 20 and multiple power supplies 10. When the testing device 30 is connected to multiple capacitive load devices 20 and multiple power supplies 10, for example, taking a testing device 30 connected to two capacitive load devices 20 and two power supplies 10, namely capacitive load device A and capacitive load device B, power supply 1 and power supply 2. The capacitive load device A and capacitive load device B can provide capacitive load for power supply 1 and power supply 2 at the same time, and the testing device 30 can test the electrical information of the power supply 1 and the power supply 2 at the same time.

FIG. 2 is a structure schematic diagram of a capacitive load device provided in an embodiment of the present application. As shown in FIG. 2, the capacitive load device 20 includes a mainboard 21, a capacitor 22, a switch 23 and a microcontroller 24. The capacitor 22, the switch 23 and the microcontroller 24 are all arranged on the mainboard 21. In one embodiment, the capacitor 22 is used to provide the capacitive load for the power supply 10 by the testing device 30. The switch 23 is connected to the capacitor 22. The switch 23 is used to control the connection and disconnection between the capacitor 22 and the power supply 10. The microcontroller 24 is used to control the connection and disconnection of the switch 23 according to a received level signal. In one embodiment, the number of capacitors 22 on the mainboard 21 can be set according to actual needs. For example, the number of capacitors 22 can be one, two, three, etc. The embodiment of the present application takes the number of capacitors 22 as two as an example. The switch 23 can be a relay switch, which is an electromagnetic relay that can use a smaller current or a lower voltage to control a switch control mode of a larger current or a higher voltage.

In some embodiments, the microcontroller 24 can be obtained by using preset software to write a program code and burning the program code into the chip, wherein the preset software and the chip type can be set according to actual needs and are not limited here. The microcontroller 24 is configured to control the switch 23 to connect the capacitor 22 to the power supply 10 when the level signal is at a first level, and to control the switch 23 to disconnect the capacitor 22 from the power supply 10 when the level signal is at the second level. In one embodiment, the first level can be a high level, a low level, a rising edge or a falling edge, and the embodiment of the present application takes the first level as a high level as an example. The second level can be a high level, a low level, a rising edge or a falling edge, and the embodiment of the present application takes the second level as a low level as an example. In some embodiments, a plurality of pins (not shown in the FIG. 2) are provided in the microcontroller 24, and one or more pins are selected from the plurality of pins as the target pins, and the level signal is used to identify a level state of the target pin in the microcontroller 24. When the level signal of the target pin is a first level (i.e., a high level), the microcontroller 24 provides a preset voltage value for the switch 23, so that the capacitor 22 is connected to the power supply 10. When the level signal of the target pin is a second level (i.e., a low level), the microcontroller 24 does not provide the preset voltage value for the switch 23, so that the capacitor 22 is disconnected from the power supply 10.

In some embodiments, please continue to refer to FIG. 1. In order to avoid welding the capacitive load device 20 and the test device 30, the capacitive load device 20 and the testing device 30 can be connected by a quick connector. The capacitive load device 20 also includes a first connection part 25, and the testing device 30 also includes a second connection part 31. The capacitive load device 20 is connected to the testing device 30 by connecting the first connection part with the second connection part 31. In one embodiment, the first connection part 25 and the second connection part 31 can be aviation male and female head wires. In the embodiment of the present application, by setting the first connection part 25 for the capacitive load device 20 and the second connection part 31 for the testing device 30, and connecting the capacitive load device 20 and the power supply 10 by the first connection part 25 and the second connection part 31, it is possible to achieve plug-and-play with the power supply 10 and improve the efficiency of electrical testing.

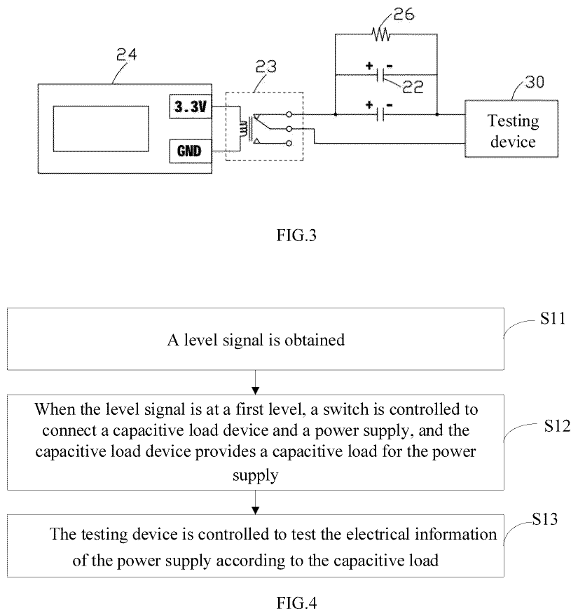

In some embodiments, the capacitive load device 20 also includes a resistor 26. The resistor 26 is connected in parallel with the capacitor 22 to provide a discharge path for the capacitor 22 to avoid damage to the circuit or capacitor device due to excessive current. A resistance of the resistor 26 can be set according to actual needs. For example, an ohmic resistor with a resistance of 1M, an ohmic resistor with a resistance of 2M, etc. can be selected, which is not limited here. FIG. 3 is a schematic diagram of an electrical testing circuit provided in an embodiment of the present application. As shown in FIG. 3, a microcontroller 24 is electrically connected to the switch 23. The resistor 26 and the capacitor 22 are connected in parallel to the circuit, and the switch 23 and the testing device 30 are connected respectively. The microcontroller 24 is used to turn on the switch 23 so that the capacitor 22 is connected to the test device 30, or to turn off the switch 23 so that the capacitor 22 is disconnected from the test device 30.

In some embodiments, although not shown, the testing device 30 includes components such as a digital multimeter, an oscilloscope, and a voltage regulator for measuring and analyzing the electrical performance of the power supply 10.

The electrical testing device provided in the embodiment of the present application sets a switch 23 for the capacitive load device 20, and then controls the switch 23 to connect or disconnect the capacitor with the power supply 10 according to the level signal received by the microcontroller 24, thereby avoiding a problem of shortening the life of the capacitive load device 20 due to repeated plugging and unplugging; and controls the switch 23 to connect or disconnect the capacitor with the power supply 10 according to the level signal, thereby realizing an automation of electrical testing and improving the accuracy and speed of electrical testing.

FIG. 4 is a flow chart of an electrical testing method provided in an embodiment of the present application. The electrical testing method is applied in an electrical testing device. As shown in FIG. 4, the method includes following steps.

At block S11, a level signal is obtained.

In some embodiments, a microcontroller is provided with a plurality of pins, and one or more pins are selected from the plurality of pins as target pins, and the level signal is used to identify the level state of the target pin in the microcontroller. In one embodiment, a read function is provided in the microcontroller, and the level state of the target pin is read by the read function. For example, the level state of the target pin can be read by using the GPIO_ReadInputDataBit function. If a returned value of the function is HIGH, it indicates that the target pin is at a high level; if the returned value of the function is LOW, it indicates that the target pin is at a low level.

S12, when the level signal is at a first level, a switch is controlled to connect a capacitive load device and a power supply, and the capacitive load device provides a capacitive load for the power supply.

In some embodiments, the first level can be a high level, a low level, a rising edge or a falling edge. In the embodiment of the present application, the first level is taken as an example of a high level. When the level signal is a high level, the microcontroller controls the switch to connect the capacitive load device to the power supply, so that the capacitive load device provides a capacitive load for the power supply.

At block S13, the testing device is controlled to test the electrical information of the power supply according to the capacitive load.

In some embodiments, the testing device tests the electrical information of the power supply under different capacitive loads (namely electrical testing) to ensure the quality of the power supply and avoid failure of the power supply during subsequent use. The electrical testing may include a voltage stability test to measure the stability of an output voltage of the power supply under different capacitive loads. The testing device monitors the output voltage of the power supply corresponding to different capacitive loads and determines the electrical information of the power supply according to the output voltage.

The electrical testing method provided in the embodiment of the present application controls the switch to connect or disconnect the capacitor and the power supply according to the level signal, thereby automating the electrical testing and improving the accuracy and speed of the electrical testing.

In some embodiments, when the level signal is at the first level, controlling the switch to connect the capacitive load device to the power supply, including: when the level signal is at the first level, the microcontroller provides a preset voltage value to the switch, so that the switch connects the capacitive load device and the power supply. In one embodiment, the preset voltage value can be determined according to the type of switch. Taking the switch as a 5VRelay switch as an example, the 5VRelay switch refers to a switch that works in the voltage range of 0 to 5V. The 5VRelay switch can turn on or turn off by receiving a 5V control signal, thereby controlling other circuits connected to the switch. In this way, the preset voltage value can be a voltage of 0to 5V, for example, the preset voltage value is 3.3V, 4V, 5V, etc., which is not limited here. The embodiment of the present application controls the switch according to the level signal to connect the capacitor to the power supply, realizes the automation of electrical testing, and improves the accuracy and speed of electrical testing.

In some embodiments, the level signal also includes a second level, and the method further includes: when the level signal is the second level, the switch is controlled to disconnect the capacitor from the power supply. The second level can be a high level, a low level, a rising edge or a falling edge, and the embodiment of the present application takes the second level as a low level as an example. When the level signal is the second level, the microcontroller provides a second level signal (i.e., a low level signal) to the switch, so that contacts of the switch are disconnected, thereby controlling the switch to disconnect the capacitor from the power supply. The switch is controlled according to the level signal to disconnect the capacitor from the power supply, thereby realizing the automation of electrical testing and improving the accuracy and speed of electrical testing.

In some embodiments, the same power supply can be connected to one or more capacitive load devices. When there are multiple capacitive load devices, the number of capacitive load devices connected to the power supply can be determined according to the capacitive load to be tested. FIG. 5 is a flow chart of a method for determining a capacitive load device provided in an embodiment of the present application. The method for determining a capacitive load device is applied to an electrical testing device. As shown in FIG. 5, the method includes following steps.

At block S21, a first capacitive load to be tested is obtained.

In some embodiments, the first capacitive load may be pre-set, and the number of the first capacitive loads may be one or more, for example, the first capacitive load may be 2F, 4F, 6F, etc., which is not limited here. The embodiment of the present application takes the first capacitive load of 4F as an example.

At block S22, a second capacitive load corresponding to each capacitive load device is obtained.

In some embodiments, each capacitor load device has a corresponding second capacitor load. The second capacitor load can be determined according to the capacity of each capacitor on the mainboard. For example, there are three capacitor load devices, namely capacitor load device A, capacitor load device B, and capacitor load device C, wherein capacitor load device A includes capacitor A1 and capacitor A2, and the capacity of capacitor A1 and capacitor A2 is 1F, so the second capacitor load of capacitor load device A can be 2F. Similarly, the second capacitor load of capacitor load device B is 2F, and the second capacitor load of 10 capacitor load device C is 4F.

At block S23, a target capacitive load device is selected from a plurality of capacitive load devices according to the first capacitive load and each second capacitive load.

In some embodiments, following the above embodiments, when the first capacitive load is 4F, the capacitive load device A and the capacitive load device B may be selected as target capacitive load devices, or the capacitive load device C may be selected as the target capacitive load device.

At block S24, the electrical testing device determines that the level signal corresponding to the target capacitive load device is a first level, and determines that the level signal corresponding to other capacitive load devices except the target capacitive load device is a second level.

In some embodiments, when the capacitive load device A and the capacitive load device B are selected as target capacitive load devices, the level signals corresponding to the capacitive load device A and the capacitive load device B may be set to the first level, and the level signal corresponding to capacitive load device C may be set to the second level. When the capacitive load device C is selected as the target capacitive load device, the level signal corresponding to capacitive load device C may be set to the first level, and the level signals corresponding to the capacitive load device A and the capacitive load device B may be set to the second level.

The embodiment of the present application determines the capacitive load device required for the electrical testing based on the first capacitive load to be tested and the second capacitive load corresponding to each capacitive load device, and determines whether the capacitive load device is connected to the power supply according to the level signal. It can respond to the electrical testing requirements and quickly and accurately determine the capacitive load device, thereby improving the accuracy and rate of the electrical testing.

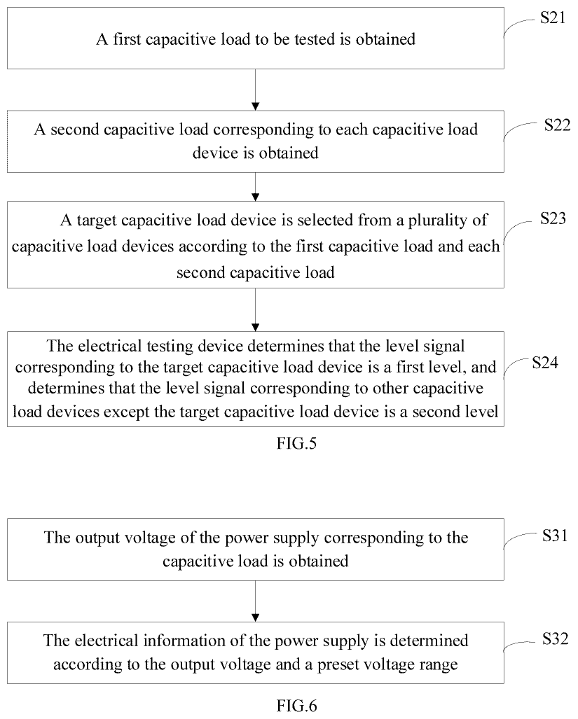

In some embodiments, the electrical testing may include a voltage stability testing, which is used to measure the stability of the output voltage of the power supply under different capacitive loads. FIG. 6 is a flow chart of a method for testing electrical information provided in an embodiment of the present application, and the method for testing electrical information is applied to an electrical testing device. As shown in FIG. 6, the method includes following steps.

At block S31, the output voltage of the power supply corresponding to the capacitive load is obtained.

In some embodiments, the testing device includes components such as a digital multimeter, an oscilloscope, and a voltage regulator for measuring and analyzing the output performance of the power supply. The testing device can obtain and record the output voltage of the power supply under different capacitive loads.

At block S32, the electrical information of the power supply is determined according to the output voltage and a preset voltage range.

In some embodiments, the preset voltage range is a voltage range when the power supply is in a stable state. If the output voltage is within the preset voltage range, the electrical information of the power supply is determined to be voltage stable; if the output voltage is not within the preset voltage range, the electrical information of the power supply is determined to be voltage unstable.

The embodiment of the present application determines the electrical information of the power supply according to the output voltage of the power supply under different capacitive loads and the preset voltage range, and can accurately evaluate the voltage stability of the power supply.

In the embodiments provided in the present application, it should be understood that the disclosed devices and methods can be implemented in other ways. For example, the device embodiments described above are only schematic, for example, the division of modules is only a logical function division, and there may be other division methods in actual implementation.

The modules described as separate components may or may not be physically separated, and the components shown as modules may or may not be physical units, and may be located in one place or distributed on multiple network units. Some or all of the modules may be selected according to actual needs to achieve the purpose of the solution of the embodiment.

In addition, each functional module in each embodiment of the present application can be integrated into one processing unit, or each unit can exist physically separately, or two or more units can be integrated into one unit. The above integrated unit can be implemented in the form of hardware or in the form of hardware plus software functional modules.

The electrical testing method is applied in the electrical testing device. The electrical testing method may include at least one processor and a storage device. The at least one processor is used to execute computer programs, such as an operating system and a system implementing the electrical testing method, installed in the electrical testing device. The processor can be a microcontroller. The storage device stores computer-readable instructions of the computer programs. The storage device can be any type of non-transitory computer-readable storage medium or other computer storage device, such as a hard disk drive, a compact disc, a digital video disc, a tape drive, a storage card (e.g., a memory stick, a smart media card, a compact flash card), or other suitable storage medium, for example.

It is obvious to those skilled in the art that the present application is not limited to the details of the above exemplary embodiments, and that the present application can be implemented in other specific forms without departing from the spirit or basic features of the present application. Therefore, from any point of view, the embodiments should be regarded as exemplary and non-restrictive, and the scope of the present application is limited by the attached claims rather than the above description, so it is intended to include all changes that fall within the meaning and scope of the equivalent elements of the claims in the present application. Any figure mark in the claims should not be regarded as limiting the claims involved. In addition, it is obvious that the word “including” does not exclude other units or, and the singular does not exclude the plural. Multiple units or devices stated in the specification can also be implemented by one unit or device by software or hardware. The words first, second, etc. are used to indicate names, and do not indicate any particular order.

Finally, it should be noted that the above embodiments are only used to illustrate the technical solution of the present application and are not intended to limit it. Although the present application has been described in detail with reference to the preferred embodiments, a person of ordinary skill in the art should understand that the technical solution of the present application may be modified or replaced by equivalents without departing from the spirit and scope of the technical solution of the present application.

What is claimed is:

1. An electrical testing device comprising:
at least one power supply;
at least one capacitive load device configured for providing a capacitive load for the power supply;
a testing device connected to the at least one capacitive load device and the at least one power supply, and configured for testing electrical information of the power supply according to the capacitive load, wherein
each of the at least one capacitive load device comprises a capacitor, a switch and a microcontroller, the capacitor is connected to the testing device and configured for providing the capacitive load for the power supply by the testing device; the switch is connected to the capacitor and configured for controlling connection and disconnection between the capacitor and the power supply; the microcontroller is connected to the switch and configured for controlling the connection and disconnection of the switch according to a level signal received by the microcontroller.

2. The electrical testing device as recited in claim 1, wherein the microcontroller is further configured for controlling the switch to connect the capacitor to the power supply when the level signal is at a first level; and the microcontroller is further configured for controlling the switch to disconnect the capacitor from the power supply when the level signal is at a second level.

3. The electrical testing device as recited in claim 1, wherein each of the at least one capacitive load device further comprises a first connection part, and the testing device further comprises a second connection part, and each of the at least one capacitive load device is connected to a power) supply testing device by connecting the first connecting part and the second connecting part.

4. The electrical testing device as recited in claim 1, wherein each of the at least one capacitive load device further comprises a resistor, and the resistor is connected in parallel with the capacitor to provide a discharge path for the capacitor.

5. The electrical testing device as recited in claim 1 comprising a plurality of power supply and a plurality of capacitive load devices, wherein the testing device is connected to the plurality of capacitive load devices and the plurality of power supplies.

6. The electrical testing device as recited in claim 1, wherein each of the at least one capacitive load device comprises a mainboard, each of the capacitor, the switch and the microcontroller is arranged on the mainboard.

7. An electrical testing method, applied in an electrical testing device, the electrical testing method comprising:
obtaining a level signal from the electrical testing device;
when the level signal is at a first level, controlling a switch to connect at least one capacitive load device to a power supply to provide a capacitive load to the power supply; and
controlling the testing device to test electrical information of the power supply according to the capacitive load.

8. The electrical testing method as recited in claim 7, wherein controlling the switch to connect the at least one capacitive load device to the power supply comprises:
providing a preset voltage value to the switch by a microcontroller, and controlling the switch to connect the at least one capacitive load device to the power supply.

9. The electrical testing method as recited in claim 7, further comprising:
when the level signal is at a second level, controlling the switch to disconnect the capacitor from the power supply by the microcontroller.

10. The electrical testing method as recited in claim 7, further comprising:
obtaining a first capacitive load to be tested;
obtaining a second capacitive load corresponding to each of a plurality of capacitive load devices;
selecting a target capacitive load device from the plurality of capacitive load devices according to the first capacitive load and each of the second capacitive loads;
determining that a level signal corresponding to the target capacitive load device is the first level, and determining that a level signal corresponding to remaining capacitive load devices is a second level.

11. The electrical testing method as recited in claim 10, wherein the method further comprises:
determining the second capacitor load according to a capacity of each of capacitors on a mainboard.

12. The electrical testing method as recited in claim 7, wherein controlling the testing device to test electrical information of the power supply according to the capacitive load, comprising:
obtaining an output voltage of the power supply corresponding to the capacitive load;
determining the electrical information of the power supply according to the output voltage and a preset voltage range.

13. The electrical testing method as recited in claim 12, wherein determining the electrical information of the power supply according to the output voltage and a preset voltage range, comprising:
when the output voltage is within the preset voltage range, determining the electrical information of the power supply to be voltage stable;
when the output voltage is not within the preset voltage range, determining the electrical information of the power supply to be voltage unstable.

14. A non-transitory storage medium having stored thereon instructions that, when executed by at least one processor of an electrical testing device, causes the least one processor to execute instructions of an electrical testing method, the method comprising:
obtaining a level signal from the electrical testing device;
when the level signal is at a first level, controlling a switch to connect at least one capacitive load device to a power supply to provide a capacitive load to the power supply; and
controlling the testing device to test electrical information of the power supply according to the capacitive load.

15. The non-transitory storage medium as recited in claim 14, wherein controlling the switch to connect the at least one capacitive load device to the power supply comprises:
providing a preset voltage value to the switch by a microcontroller, and controlling the switch to connect the at least one capacitive load device to the power supply.

16. The non-transitory storage medium as recited in claim 14, wherein the method further comprises:
when the level signal is at a second level, controlling the switch to disconnect the capacitor from the power supply by the microcontroller.

17. The non-transitory storage medium as recited in claim 14, wherein the method further comprises:
obtaining a first capacitive load to be tested;
obtaining a second capacitive load corresponding to each of a plurality of capacitive load devices;
selecting a target capacitive load device from the plurality of capacitive load devices according to the first capacitive load and each of the second capacitive loads;
determining that a level signal corresponding to the target capacitive load device is the first level, and determining that a level signal corresponding to remaining capacitive load devices is a second level.

18. The non-transitory storage medium as recited in claim 17, wherein the method further comprises:
determining the second capacitor load according to a capacity of each of capacitors on a mainboard.

19. The non-transitory storage medium as recited in claim 14, wherein controlling the testing device to test electrical information of the power supply according to the capacitive load, comprising:
obtaining an output voltage of the power supply corresponding to the capacitive load;
determining the electrical information of the power supply according to the output voltage and a preset voltage range.

20. The non-transitory storage medium as recited in claim 12, wherein determining the electrical information of the power supply according to the output voltage and a preset voltage range, comprising:
when the output voltage is within the preset voltage range, determining the electrical information of the power supply to be voltage stable;
when the output voltage is not within the preset voltage range, determining the electrical information of the power supply to be voltage unstable.
